(19) United States
(12) Patent Application Publication
(10) Pub. No.: US 2025/0107084 A1
(43) Pub. Date: Mar. 27, 2025

(54) SEMICONDUCTOR DEVICE, METHOD OF MANUFACTURING THE SEMICONDUCTOR DEVICE, AND METHOD OF OPERATING THE SEMICONDUCTOR DEVICE

(71) Applicant: SK hynix Inc., Icheon-si Gyeonggi-do (KR)

(72) Inventor: Sung Wook JUNG, Icheon-si Gyeonggi-do (KR)

(73) Assignee: SK hynix Inc., Icheon-si Gyeonggi-do (KR)

(21) Appl. No.: 18/592,052

(22) Filed: Feb. 29, 2024

(30) Foreign Application Priority Data
Sep. 26, 2023 (KR) 10-2023-0128937

(51) Int. Cl. H10B 43/27; G11C 5/06; G11C 16/04

(52) U.S. Cl. CPC H10B 43/27; G11C 5/063; G11C 16/0483

(57) ABSTRACT

The present technology relates to a semiconductor device, a method of manufacturing the same, and a method of operating the same. The semiconductor device includes a gate stack including first interlayer insulating layers and word line stack layers alternately stacked, a vertical channel structure extending in a vertical direction in the gate stack, and memory structures interposed between the word line stack layers and the vertical channel structure, each of the word line stack layers includes an even conductive layer, a second interlayer insulating layer, and an odd conductive layer sequentially stacked, and a thickness of any one of the first interlayer insulating layers is greater than a thickness of any one of the second interlayer insulating layers.

### CROSS-REFERENCE TO RELATED APPLICATION

The present application claims priority under 35 U.S.C. § 119 (a) to Korean patent application number 10-2023-0128937 filed on Sep. 26, 2023, in the Korean Intellectual Property Office, the entire disclosure of which is incorporated by reference herein.

### BACKGROUND

### 1. Technical Field

The present disclosure relates to an electronic device, and more particularly, to a semiconductor device, a method of manufacturing the semiconductor device, and a method of operating the semiconductor device.

### 2. Related Art

A non-volatile memory device is a memory device that retains stored data even though its power supply is cut off. Recently, as improvements in the integration degrees of two-dimensional non-volatile memory devices that form a memory cell in a single layer on a substrate has reached a maximum limit, three-dimensional non-volatile memory devices that stack memory cells vertically on a substrate have been proposed.

The three-dimensional non-volatile memory device includes alternately stacked interlayer insulating layers and gate electrodes, and channel layers passing through the interlayer insulating layers and the gate electrodes, and memory cells are stacked along the channel layers. In order to improve operation reliability of the non-volatile memory device having this three-dimensional structure, various structures and manufacturing methods are being developed.

### SUMMARY

According to an embodiment of the present disclosure, a semiconductor device may include a gate stack including first interlayer insulating layers and word line stack layers, which are alternately stacked, a channel layer extending in a vertical direction in the gate stack, and memory structures interposed between the word line stack layers and the channel layer, each of the word line stack layers includes an even conductive layer, a second interlayer insulating layer, and an odd conductive layer sequentially stacked, and the thickness of each of the first interlayer insulating layers is greater than the thickness of any one of the second interlayer insulating layers included in any one of the word line stack layers.

According to an embodiment of the present disclosure, a method of manufacturing a semiconductor device may include forming a stack structure by alternately stacking first material layers and multi-stack layers, in which each of the multi-stack layers includes a second material layer, a third material layer, and another second material layer sequentially stacked, forming a vertical hole at least partially passing through the stack structure forming recess regions by etching to a certain depth a sidewall of the second material layer exposed through the vertical hole, forming blocking insulating layers by oxidizing a sidewall of the second material layers exposed through the recess regions, forming charge trap layers in each of the recess regions, in which the charge trap layers are spaced apart from each other in a vertical direction by the first material layers and the third material layers, and sequentially forming a tunnel insulating layer and a channel layer along a sidewall of the vertical hole, and a thickness of any one of the first material layers is greater than a thickness of any one of the third material layers.

According to an embodiment of the present disclosure, a semiconductor device may include a gate stack including first interlayer insulating layers and word line stack layers, which are alternately stacked, a channel layer extending in a vertical direction in the gate stack, and memory structures interposed between the word line stack layers and the channel layer, each of the word line stack layers includes an even conductive layer, a second interlayer insulating layer, and an odd conductive layer sequentially stacked, each of the memory structures includes a blocking insulating layer, a charge trap layer, and a tunnel insulating layer sequentially interposed between sidewalls of the even conductive layer and the odd conductive layer, and a thickness of each any one of the first interlayer insulating layers is greater than a thickness of any one of the second interlayer insulating layers.

According to an embodiment of the present disclosure, a method of manufacturing a semiconductor device may include forming a stack structure by alternately stacking first material layers and multi-stack layers, in which each of the multi-stack layers includes a second material layer, a third material layer, and another second material layer sequentially stacked, forming a vertical hole at least partially passing through the stack structure, forming first recess regions by etching to a certain depth a sidewall of the second material layer exposed through the vertical hole, forming blocking insulating layers by oxidizing a sidewall of the second material layers exposed through the first recess regions, forming charge trap layers in each of the first recess regions, in which the charge trap layers are spaced apart from each other in a vertical direction by the first material layers and the third material layer, forming second recess regions by etching to a certain depth a sidewall of the charge trap layers exposed through the vertical holes, forming tunnel insulating layers in each of the second recess regions, and forming a channel layer along a sidewall of the vertical hole.

According to an embodiment of the present disclosure, a method of operating a semiconductor device may include providing a memory cell array including a first memory group, a first interlayer insulating layer, and a second memory group stacked in a vertical direction, in which each of the first memory group and the second memory group includes an even memory cell, a second interlayer insulating layer, and an odd memory cell stacked in the vertical direction, and a thickness of any one of the first interlayer insulating layer is greater than a thickness of any one of the second interlayer insulating layer, programming the even memory cell of the first memory group in a first program method, and programming the odd memory cell of the first memory group in a second program method, and the first program method is a program method in which a storage bit is relatively high compared to the second program method.

According to an embodiment of the present disclosure, a method of operating a semiconductor device may include providing a memory cell array including a first memory group, a first interlayer insulating layer, and a second memory group stacked in a vertical direction, in which each of the first memory group and the second memory group includes an even memory cell, a second interlayer insulating layer, and an odd memory cell stacked in the vertical direction, and a thickness of any one of the first interlayer insulating layers is greater than a thickness of any one of the second interlayer insulating layers, reading the even memory cell of the first memory group, and reading the odd memory cell of the first memory group, and reading the even memory cell of the first memory group includes applying a read voltage to the even memory cell of the first memory group, applying a first pass voltage to the odd memory cell of the first memory group, and applying a second pass voltage higher than the first pass voltage to the even memory cell and the odd memory cell of the second memory group.

### BRIEF DESCRIPTION OF THE DRAWINGS

FIG. 1 is a diagram illustrating a semiconductor device according to an embodiment of the present disclosure.

FIG. 2 is a circuit diagram illustrating a memory cell array of a semiconductor device according to an embodiment of the present disclosure.

FIG. 3 is a cross-sectional view illustrating a memory cell array of a semiconductor device according to an embodiment of the present disclosure.

FIGS. 4A, 4B, 4C, 4D, 4E, and 4F are cross-sectional views illustrating a method of manufacturing a semiconductor device according to an embodiment of the present disclosure.

FIG. 5 is a cross-sectional view illustrating a memory cell array of a semiconductor device according to another embodiment of the present disclosure.

FIGS. 6A, 6B, 6C, 6D, 6E, 6F, and 6G are cross-sectional views illustrating a method of manufacturing a semiconductor device according to another embodiment of the present disclosure.

FIG. 7 is a flowchart illustrating a program method of a semiconductor device according to an embodiment of the present disclosure.

FIG. 8 is a flowchart illustrating a read method of a semiconductor device according to an embodiment of the present disclosure.

FIG. 9 is a diagram illustrating a solid state drive (SSD) system to which a semiconductor device of the present disclosure is applied.

### DETAILED DESCRIPTION

Specific structural or functional descriptions of embodiments according to the concept which are disclosed in the present specification or application are illustrated only to describe the embodiments according to the concept of the present disclosure. The embodiments according to the concept of the present disclosure may be carried out in various forms and should not be construed as being limited to the embodiments described in the present specification or application.

An embodiment of the present disclosure provides a semiconductor device, a method of manufacturing the semiconductor device, and a method of operating the semiconductor device in which an integration degree of memory cells is improved by narrowing a gap between at least two memory cells adjacent in a vertical direction among a plurality of memory cells stacked in the vertical direction.

In various embodiments, an integration degree of memory cells may be improved by narrowing a gap between at least two memory cells adjacent in a vertical direction among a plurality of memory cells stacked in the vertical direction. In addition, during program and read operations, in an embodiment, a pass voltage applied to a memory cell adjacent to a selected memory cell may be applied lower than a pass voltage applied to other memory cells, thereby improving a disturb phenomenon.

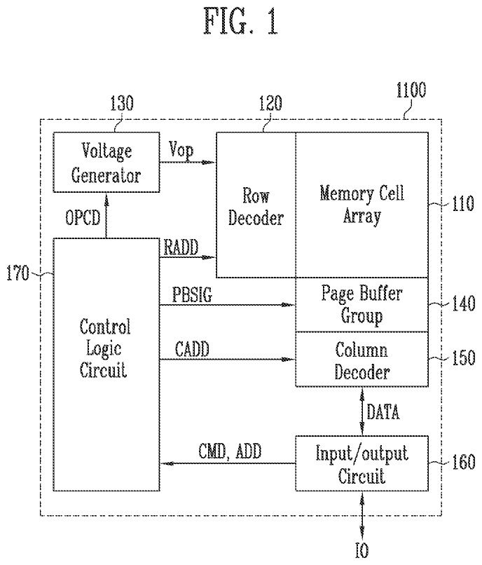

FIG. 1 is a diagram illustrating a semiconductor device according to an embodiment of the present disclosure.

Referring to FIG. 1, the memory device 1100 may include a memory cell array 110 in which data is stored, and a peripheral circuit including elements 120 to 170 that are capable of performing a program, read, or erase operation.

The memory cell array 110 may include a plurality of memory blocks in which data is stored. Each of the memory blocks includes a plurality of memory cells, and the plurality of memory cells may be non-volatile memory cells. The non-volatile memory cells may be implemented in a three-dimensional structure in which the non-volatile memory cells are stacked on a substrate in a vertical direction.

The peripheral circuit including elements 120 to 170 may include a row decoder 120, a voltage generator 130, a page buffer group 140, a column decoder 150, and an input/output circuit 160, and a control logic circuit 170.

The row decoder 120 may select one memory block from among the memory blocks included in the memory cell array 110 according to a row address RADD, and transmit operation voltages Vop to the selected memory block.

The voltage generator 130 may generate and output the operation voltages Vop required for various operations, in response to an operation code OPCD. For example, the voltage generator 130 may generate a set voltage, a reset voltage, a turn-on voltage, a turn-off voltage, a read voltage, an erase voltage, or the like in response to the operation code OPCD and selectively output the generated voltages. According to the present embodiment, the voltage generator 130 may generate voltages equal to or greater than OV as voltages to be applied to word lines, and may also include a device that generates a negative voltage less than OV.

The page buffer group 140 may be connected to the memory cell array 110 through bit lines. For example, the page buffer group 140 may include page buffers connected to each of the bit lines. The page buffers may operate simultaneously in response to page buffer control signals PBSIG, and may store data during the program or read operation. During the read operation or a verify operation, the page buffers may sense a current of the bit lines, which varies according to a threshold voltage of the memory cells. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

The column decoder 150 may transmit data DATA between the input/output circuit 160 and the page buffer group 140 according to a column address CADD.

The input/output circuit 160 may be connected to an external device through input/output lines IO. For example, the external device may be a controller capable of transmitting a command CMD, an address ADD, or the data DATA to the semiconductor device 1100. The input/output circuit 160 may input and output the command CMD, the address ADD, and the data DATA through the input/output lines IO. For example, the input/output circuit 160 may transmit the command CMD and the address ADD received from the external device through the input/output lines IO to the control logic circuit 170, and transmit the data DATA received from the external device through the input/output lines IO to the column decoder 150. The input/output circuit 160 may output the data DATA received from the column decoder 150 to the external device through the input/output lines IO.

The control logic circuit 170 may output the operation code OPCD, the row address RADD, the page buffer control signals PBSIG, and the column address CADD in response to the command CMD and the address ADD. For example, the control logic circuit 170 may include software that performs an algorithm in response to the command CMD, and hardware configured to output the address ADD and various signals.

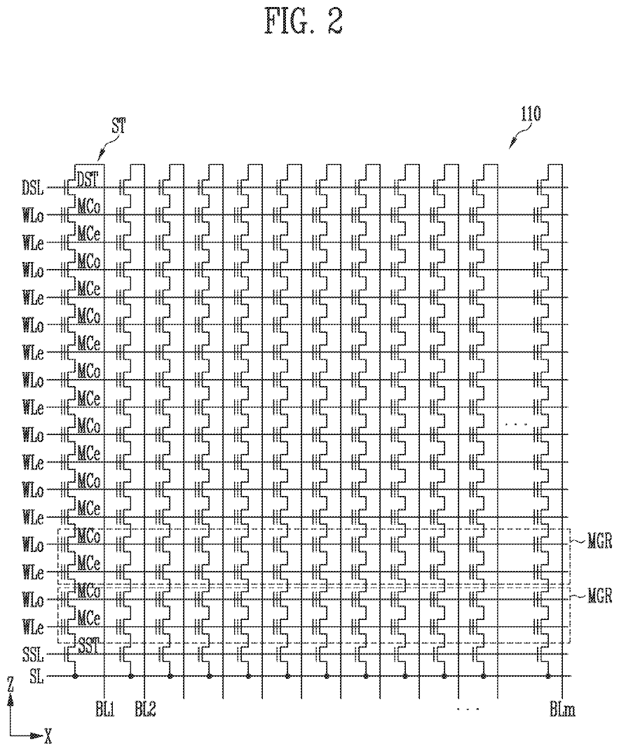

FIG. 2 is a circuit diagram illustrating a memory cell array of a semiconductor device according to an embodiment of the present disclosure.

Referring to FIG. 2, a plurality of even word lines WLe and a plurality of odd word lines WLo arranged in parallel between a first selection line and a second selection line may be connected to the memory cell array 110. Here, the first selection line may be a source selection line SSL, and the second selection line may be a drain selection line DSL. For example, the memory cell array 110 may include a plurality of memory strings ST connected between bit lines BL1 to BLm and a source line SL. The bit lines BL1 to BLm may be respectively connected to the memory strings ST, and the source line SL may be commonly connected to the memory strings ST.

Because the memory strings ST may be configured identically to each other, the memory string ST connected to a first bit line BL1 is specifically described as an example.

The memory string ST may include a source selection transistor SST, a plurality of even memory cells MCe, a plurality of odd memory cells MCo, and a drain selection transistor DST connected in series between the source line SL and the first bit line BL1. In one memory string ST, at least one or more source selection transistors SST and at least one or more drain selection transistors DST may be included, and the plurality of even memory cells MCe and the plurality of odd memory cells MCo of the number greater than that shown in the drawing may also be included. The plurality of even memory cells MCe and the plurality of odd memory cells MCo may be alternately disposed. The source selection transistor SST, the plurality of even memory cells MCe, the plurality of odd memory cells MCo, and the drain selection transistor DST may be stacked and disposed in a first direction Z, which is a vertical direction of a substrate.

A source of the source selection transistor SST may be connected to the source line SL, and a drain of the drain selection transistor DST may be connected to the first bit line BL1. The plurality of even memory cells MCe and the plurality of odd memory cells MCo may be alternately connected in series between the source selection transistor SST and the drain selection transistor DST. Gates of the source selection transistors SST included in the different memory strings ST may be connected to the source selection line SSL, gates of the drain selection transistors DST may be connected to the drain selection line DSL, gates of the plurality of even memory cells MCe may be respectively connected to the plurality of even word lines WLe, and gates of the plurality of odd memory cells MCo may be respectively connected to the plurality of odd word lines WLo. The plurality of even word lines WLe and the plurality of odd word lines WLo may extend in a second direction X, which is a horizontal direction of the substrate. The second direction X may be orthogonal to the first direction Z.

The plurality of even memory cells MCe and the plurality of odd memory cells MCo connected to one even word line WLe and one odd word line WLo disposed adjacent to each other, respectively, may be defined as one memory group MGR. The plurality of even memory cells MCe and the plurality of odd memory cells MCo included in one memory group MGR may be programmed in different program methods. For example, the plurality of even memory cells MCe included in one memory group MGR may be programmed in a quadruple level cell (QLC) method, and the plurality of odd memory cells MCo may be programmed in a triple level cell (TLC) method. As another embodiment, the plurality of even memory cells MCe included in one memory group MGR may be programmed in the QLC method, and the plurality of odd memory cells MCo may be programmed in a multi-level cell (MLC) method. The program operation of the semiconductor device may be performed in a page unit. For example, a program operation of the even memory cells MCe connected to the even word line WLe included in one memory group MGR may be performed, and then a program operation of the odd memory cells MCo connected to the odd word line WLo may be performed. During the program operation of the semiconductor device, memory cells programmed first among the even memory cells MCe and the odd memory cells MCo included in one memory group MGR may be programmed in a program method in which a storage bit of the memory cells is relatively high, and memory cells programmed after this may be programmed in a program method in which a storage bit of the memory cells is relatively low. For example, when the program operation of the even memory cells MCe connected to the even word line WLe included in one memory group MGR is performed, and then the program operation of the odd memory cells MCo connected to the odd word line WLo is performed, the even memory cells MCe connected to the even word line WLe may be programmed in the QLC method in which a storage bit is relatively high, and the odd memory cells MCo connected to the odd word line WLo may be programmed in the TLC or MLC method in which a storage bit is relatively low.

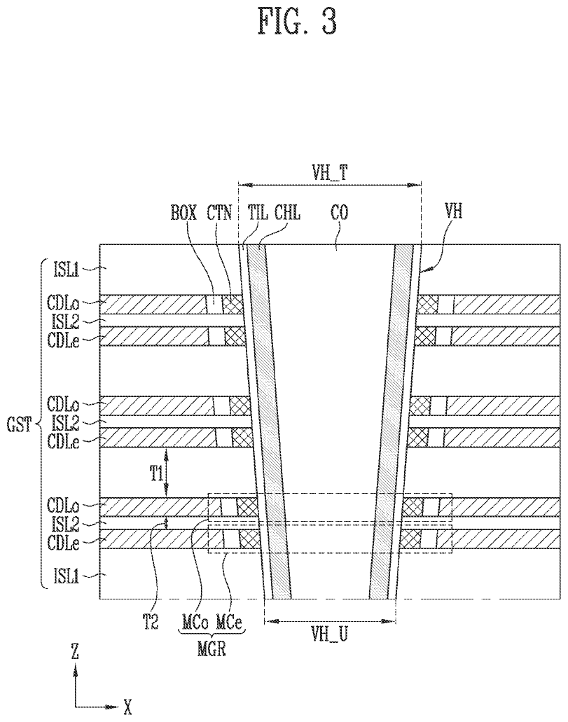

FIG. 3 is a cross-sectional view illustrating a memory cell array of a semiconductor device according to an embodiment of the present disclosure. FIG. 3 shows a portion of the memory string ST of FIG. 2.

Referring to FIG. 3, the memory string may include the plurality of even memory cells MCe and odd memory cells MCo, and the plurality of even memory cells MCe and odd memory cells MCo may be connected to even conductive layers CDLe corresponding to even word lines and odd conductive layers CDLo corresponding to odd word lines. Each of the even memory cells MCe and the odd memory cells MCo may include a blocking insulating layer BOX, a charge trap layer CTN, a tunnel insulating layer TIL, and a channel layer CHL.

One even memory cell MCe and one odd memory cell MCo adjacent to each other in the first direction Z, which is the vertical direction, may be included in one memory group MGR.

A first interlayer insulating layer ISL1 may be formed between the memory groups MGR adjacent in the first direction Z, and a second interlayer insulating layer ISL2 may be formed between one even memory cell MCe and one odd memory cell MCo included in one memory group MGR. The first interlayer insulating layer ISL1 and the second interlayer insulating layer ISL2 extend in the horizontal direction and are disposed between the even conductive layers CDLe and the odd conductive layers CDLo connected to the even memory cell MCe and the odd memory cells MCo, respectively. The thickness T2 of the second interlayer insulating layer ISL2 may be less than the thickness T1 of the first interlayer insulating layer ISL1. That is, in an embodiment, the thickness T2 of the second interlayer insulating layer ISL2 disposed between one even memory cell MCe and one odd memory cell MCo adjacent in the first direction Z included in one memory group MGR may be less than the thickness T1 of the first interlayer insulating layer ISL1 disposed between the memory groups MGR adjacent in the first direction Z.

A gate stack GST may be configured by including the even conductive layers CDLe, the odd conductive layers CDLo, the first interlayer insulating layers ISL1, and the second interlayer insulating layers ISL2. One even conductive layer CDLe, one second interlayer insulating layer ISL2, and one odd conductive layer CDLo corresponding to one memory group MGR may be defined as one word line stack layer. For example, the first interlayer insulating layers ISL1 and a plurality of word line stack layers may be alternately stacked on a lower structure (not shown). The lower structure may include the substrate or at least one of a source line, a source selection line, and peripheral circuits formed on the substrate. In an embodiment, even conductive layers CDLe and odd conductive layers CDLo may be referred to generally as conductive layers CDL.

The even conductive layers CDLe and the odd conductive layers CDLo may be used as a word line or a selection line. For example, assuming that the first interlayer insulating layers ISL1 and the plurality of word line stack layers are alternately stacked on the substrate, at least one even conductive layer CDLe disposed at the lowermost end and at least one odd conductive layer CDLo disposed at the uppermost end may be used as the selection line. For example, the uppermost one odd conductive layer CDLo disposed in the highest first direction Z as compared to the other conductive layers, as shown in FIG. 3, may be a selection line. For example, the lowermost one even conductive layer CDLe disposed in the bottom most first direction Z as compared to the other conductive layers, as shown in FIG. 3, may be a selection line.

The first interlayer insulating layers ISL1 and the second interlayer insulating layers ISL2 may be formed of oxide, and the even conductive layers CDLe and the odd conductive layers CDLo may include a conductive material such as polysilicon, tungsten, molybdenum, or metal.

In the memory string, a vertical hole VH passing through the first interlayer insulating layers ISL1, the second interlayer insulating layers ISL2, the even conductive layers CDLe, and the odd conductive layers CDLo in the first direction Z which is the vertical direction may be formed. The width of vertical hole VH may decrease as measured toward a lower end portion. For example, the width of a lower end vertical hole VH_U may be less than a width VH_T of an upper end vertical hole.

The first interlayer insulating layers ISL1 and the second interlayer insulating layers ISL2 may protrude further in a direction adjacent to the vertical hole VH compared to the even conductive layers CDLe and the odd conductive layers CDLo. That is, the blocking insulating layer BOX and the charge trap layer CTN may be interposed in a space between protrusions of the first interlayer insulating layers ISL1 and the second interlayer insulating layers ISL2 adjacent to each other in the first direction Z. That is, the blocking insulating layer BOX and the charge trap layer CTN may be interposed between the even conductive layers CDLe and the odd conductive layers CDLo and the vertical hole VH. In an embodiment of the present disclosure, the blocking insulating layer BOX and the charge trap layer CTN may be defined as a memory structure.

The tunnel insulating layer TIL and the channel layer CHL may be sequentially interposed along a sidewall of the vertical hole VH. For example, the tunnel insulating layer TIL may be interposed along the sidewall of the vertical hole VH, that is, a sidewall of the first interlayer insulating layers ISL1, the second interlayer insulating layers ISL2, and the charge trap layer CTN, and the channel layer CHL may be interposed along a sidewall of the tunnel insulating layer TIL. A core insulating layer CO may be interposed in a central region of the vertical hole VH. In an embodiment of the present disclosure, the tunnel insulating layer TIL, the channel layer CHL, and the core insulating layer CO may be defined as a vertical channel structure.

The tunnel insulating layer TIL may be a layer through which a charge is tunneled by F-N tunneling or the like, and may include an insulating material such as oxide or nitride. The charge trap layer CTN may include a plurality of trap sites, and charges flowing through the tunnel insulating layer TIL during the program operation may be trapped. The charge trap layer CTN may include nitride, chalcogenide compound, or metal oxide. The blocking insulating layer BOX may prevent or mitigate the trapped charge in the charge trap layer CTN from moving to the even conductive layers CDLe or the odd conductive layers CDLo, and may include a high dielectric constant material such as aluminum oxide Al₂O₃, hafnium oxide layer HfOx, and hafnium silicon oxide HfSiOx. The channel layer CHL may be used to allow a current to flow in the memory string, and may be formed of polysilicon.

In an embodiment, the channel layer CHL may have a cylindrical shape structure extending in the first direction Z which is the vertical direction in the vertical hole VH. The tunnel insulating layer TIL may extend in the first direction Z which is the vertical direction in the vertical hole VH and may be formed to surround an outer sidewall of the channel layer CHL.

The charge trap layer CTN may be formed to surround a portion of an outer sidewall of the tunnel insulating layer TIL, and the charge trap layer CTN corresponding to one memory cell may have a structure separated from the charge trap layer CTN corresponding to another memory cell adjacent in the first direction Z which is the vertical direction by the first interlayer insulating layer ISL1 or the second interlayer insulating layer ISL2. Accordingly, in an embodiment, an interference phenomenon and a disturb phenomenon between memory cells adjacent in the first direction Z may be reduced.

In addition, the blocking insulating layer BOX may be formed to surround an outer sidewall of the charge trap layer CTN, and the blocking insulating layer BOX corresponding to one memory cell may have a structure separated from each other by the blocking insulating layer BOX corresponding to another memory cell adjacent in the first direction Z which is the vertical direction by the first interlayer insulating layer ISL1 or the second interlayer insulating layer ISL2.

The vertical thickness of the blocking insulating layer BOX and the vertical thickness of the charge trap layer CTN corresponding to one non-volatile memory cell MC may be the same. In an embodiment, the vertical thickness of a layer may be measured in the first direction Z. A sidewall that is in contact with the vertical hole VH of the first interlayer insulating layer ISL1 or the second interlayer insulating layer ISL2 may be positioned on the same line as a sidewall that is in contact with the vertical hole VH of the charge trap layer CTN, or may be formed so that a side portion that is in contact with the vertical hole VH of the first insulating layer ISL1 or the second interlayer insulating layer ISL2 protrudes compared to a sidewall that is in contact with the vertical hole VH of the charge trap layer CTN. In addition, upper surface heights of the even conductive layer CDLe or the odd conductive layer CDLo, the blocking insulating layer BOX, and the charge trap layer CTN corresponding to one memory cell may be the same. In addition, lower surface heights of the even conductive layer CDLe or the odd conductive layer CDLo, the blocking insulating layer BOX, and the charge trap layer CTN corresponding to one memory cell may be the same. For example, the lower surface heights of the even conductive layer CDLe or the odd conductive layer CDLo, the blocking insulating layer BOX, and the charge trap layer CTN corresponding to one memory cell may be the same as shown in FIG. 3.

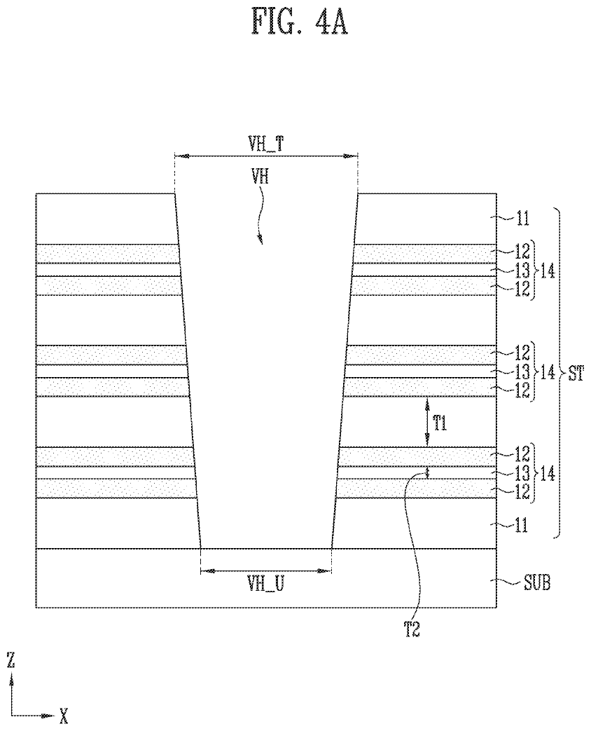

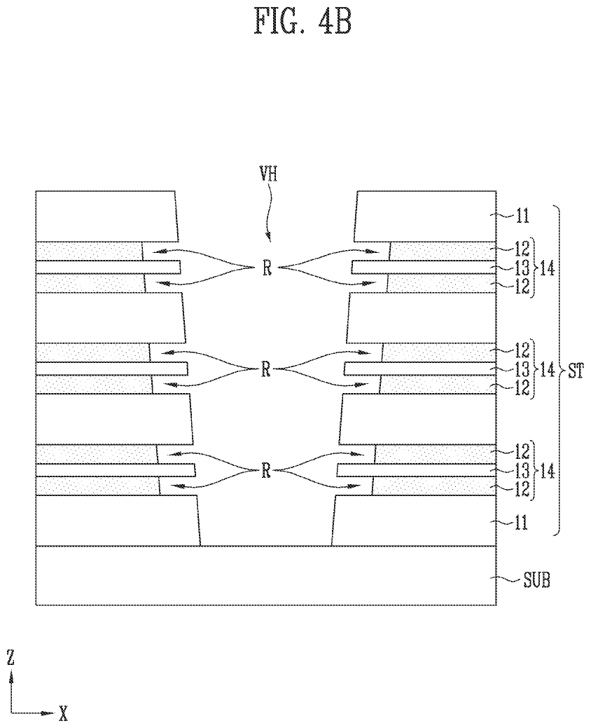

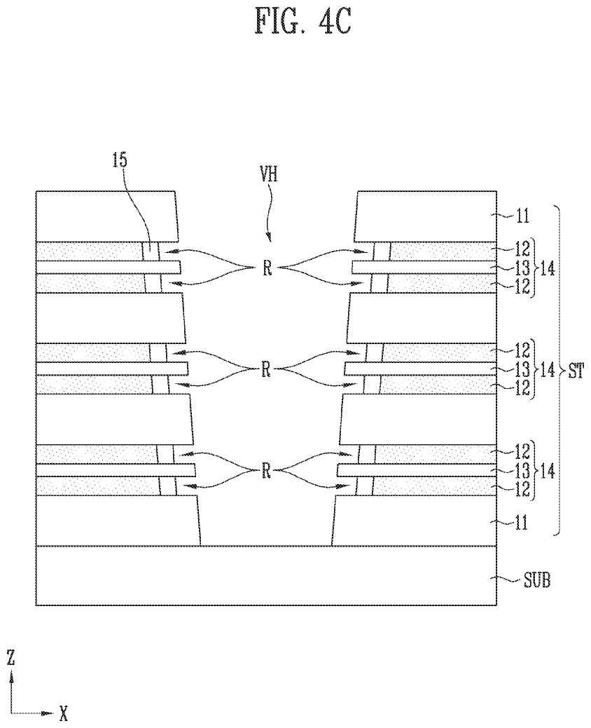

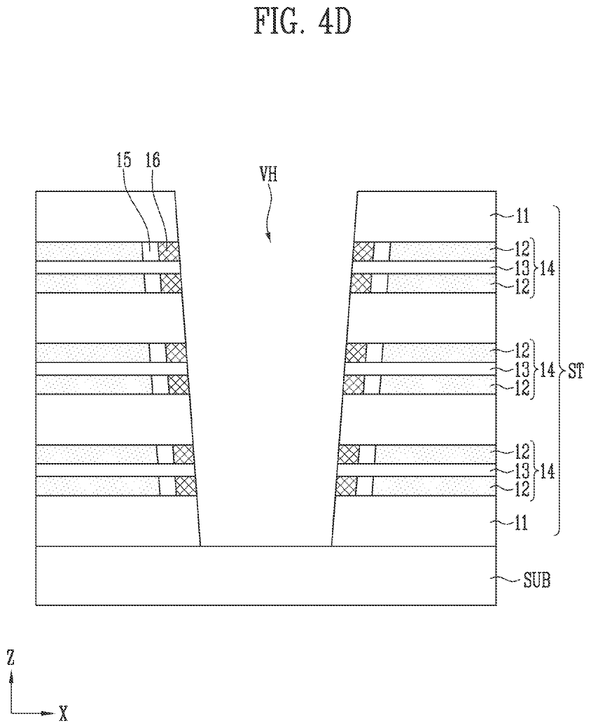

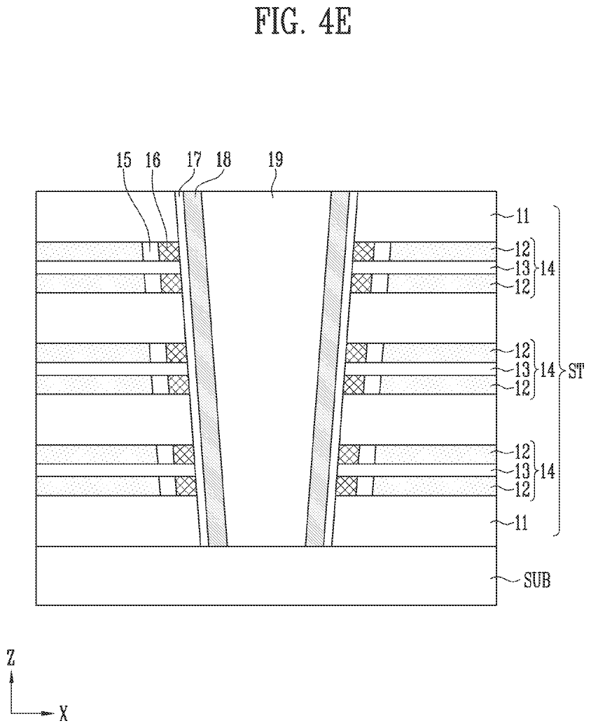

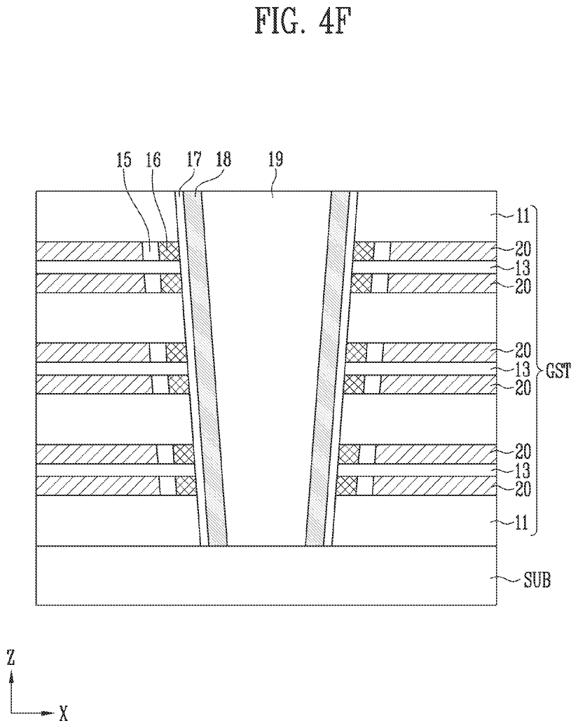

FIGS. 4A to 4F are cross-sectional views illustrating a method of manufacturing a semiconductor device according to an embodiment of the present disclosure.

Referring to FIG. 4A, a stack structure ST is formed on a substrate SUB. The stack structure ST may include first material layers 11 and multi-stack layers 14 alternately stacked. Each of the multi-stack layers 14 may include a second material layer 12, a third material layer 13, and another second material layer 12 sequentially stacked. The first material layers 11, the second material layers 12, and the third material layers 13 may extend in the second direction X which is the horizontal direction of the substrate SUB. The first material layers 11, the second material layers 12, and the third material layers 13 may be stacked in the first direction Z which is the vertical direction of the substrate SUB. The first material layers 11, the second material layers 12, and the third material layers 13 may be formed using a deposition process such as chemical vapor deposition (CVD).

A thickness T1 of the first material layers 11 may be greater than a thickness T2 of the third material layers 13.

The first material layers 11 and the third material layers 13 may include a material having a high etch selectivity with respect to the second material layers 12. As an example, the first material layers 11 and the third material layers 13 may include an insulating material such as oxide, and the second material layers 12 may include a sacrificial material such as nitride. As another example, the first material layers 11 and the third material layers 13 may include an insulating material such as oxide, and the second material layers 12 may include a conductive material such as polysilicon, tungsten, molybdenum, or metal.

Subsequently, the vertical hole VH passing through the stack structure ST may be formed. The vertical hole VH may be a cylindrical shape extending in the first direction Z. The vertical hole VH may be formed so that the width VH_T of an upper portion is greater than the width VH_U of a lower portion.

Referring to FIG. 4B, a sidewall of the second material layers 12 exposed through the vertical hole VH may be etched at a certain depth to form a recess region R. That is, the sidewall of the second material layers 12 is etched at a certain depth so that the first material layers 11 and the third material layers 13 protrude compared to the second material layers 12 in the second direction X. Accordingly, a sidewall of the vertical hole VH may be formed in a structure in which uneven portions are sequentially disposed in the first direction Z which is the vertical direction of the substrate SUB.

Referring to FIG. 4C, an oxidation process is performed to oxidize the sidewall of the second material layers 12 exposed through the vertical hole VH to form a blocking insulating layer 15. The oxidation process may be performed as a radical oxidation process or a wet oxidation process. The sidewall of the second material layers 12 may be oxidized at a certain thickness (i.e., in the X directions) by the oxidation process to form the blocking insulating layer 15.

Referring to FIG. 4D, a charge trap layer 16 is formed in the recess region R of FIG. 4C. For example, the charge trap layer 16 may be formed along the sidewall of the vertical hole VH, and the charge trap layer 16 may be formed by controlling a thickness so that the recess region R of FIG. 4C is completely buried. Subsequently, a charge trap layer 16 remains only in the recess region R of FIG. 4C by etching a portion of the charge trap layer 16. That is, the charge trap layer formed on a sidewall of the first material layer 11 and the third material layer 13 is removed by etching to physically and electrically separate the charge trap layers 16 formed in the recess region R of FIG. 4C from each other in the first direction Z. That is, the charge trap layers 16 adjacent in the first direction Z have a structure spaced apart from each other by the first material layer 11 and the third material layer 13.

The charge trap layer 16 may include a charge trap material, nitride, a variable resistance material or a nanostructure, a chalcogenide compound, a metal oxide, or a combination thereof.

Referring to FIG. 4E, a tunnel insulating layer 17 and a channel layer 18 are sequentially formed along the sidewall of the vertical hole VH of FIG. 4D. The tunnel insulating layer 17 may be a layer through which a charge is tunneled by F-N tunneling or the like, and may include an insulating material such as oxide or nitride. The channel layer 18 may include polysilicon.

The tunnel insulating layer 17 may be formed along the sidewall of the first material layers 11 and the third material layers 13 and a sidewall of the charge trap layers 16. The tunnel insulating layer 17 and the channel layer 18 may be formed to extend in the first direction Z.

Subsequently, a core insulating layer 19 may be formed to fill a central region of the vertical hole VH of FIG. 4D. The core insulating layer 19 may include oxide. When the central region of the vertical hole VH of FIG. 4D is filled with the channel layer 18, a process of forming the core insulating layer 19 may be skipped. Referring to FIG. 4F, the second material layers 12 of FIG. 4D are replaced with conductive layers 20. For example, the stack structure ST of FIG. 4D is etched to form a slit (not shown) extending in the first direction Z to expose a sidewall of the second material layers 12 of FIG. 4D. Subsequently, the second material layers 12 of FIG. 4D exposed through the slit are selectively etched and removed, and a space where the second material layers 12 of FIG. 4D are removed are filled with a conductive material to form the conductive layers 20.

The first material layers 11, the third material layers 13, and the conductive layers 20 may be defined as the gate stack GST. The first material layers 11 may correspond to the first interlayer insulating layer ISL1 of FIG. 3, the third material layers 13 may correspond to the second interlayer insulating layers ISL2 of FIG. 3, and the conductive layers 20 may correspond to the even conductive layers CDLe and the odd conductive layers CDLo of FIG. 3.

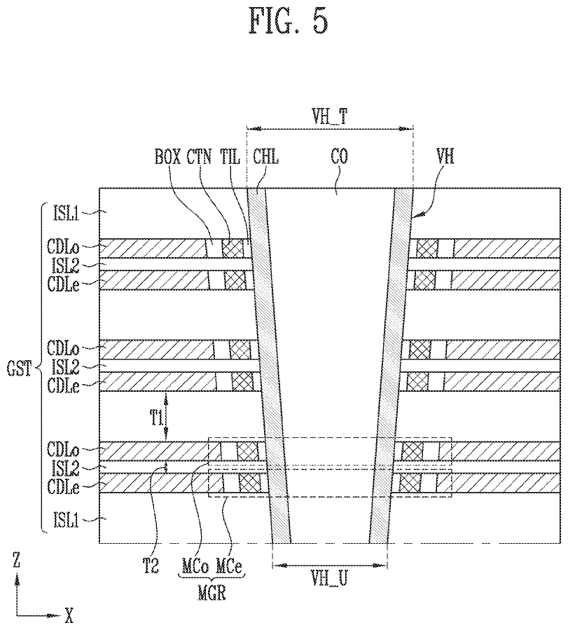

FIG. 5 is a cross-sectional view illustrating a memory cell array of a semiconductor device according to another embodiment of the present disclosure. FIG. 5 shows a portion of the memory string ST of FIG. 2.

Referring to FIG. 5, the memory string may include the plurality of even memory cells MCe and odd memory cells MCo, and the plurality of even memory cells MCe and odd memory cells MCo may be connected to even conductive layers CDLe corresponding to even word lines and odd conductive layers CDLo corresponding to odd word lines. Each of the even memory cells MCe and the odd memory cells MCo may include a blocking insulating layer BOX, a charge trap layer CTN, a tunnel insulating layer TIL, and a channel layer CHL.

One even memory cell MCe and one odd memory cell MCo adjacent to each other in the first direction Z, which is the vertical direction, may be included in one memory group MGR.

A first interlayer insulating layer ISL1 may be formed between the memory groups MGR adjacent in the first direction Z, and a second interlayer insulating layer ISL2 may be formed between one even memory cell MCe and one odd memory cell MCo included in one memory group MGR. The first interlayer insulating layer ISL1 and the second interlayer insulating layer ISL2 extend in the horizontal direction and are disposed between the even conductive layers CDLe and the odd conductive layers CDLo connected to the even memory cell MCe and the odd memory cells MCo, respectively. The thickness T2 of the second interlayer insulating layer ISL2 may be less than a thickness T1 of the first interlayer insulating layer ISL1. That is, the thickness T2 of the second interlayer insulating layer ISL2 disposed between one even memory cell MCe and one odd memory cell MCo adjacent in the first direction Z included in one memory group MGR may be less than the thickness T1 of the first interlayer insulating layer ISL1 disposed between the memory groups MGR adjacent in the first direction Z.

A gate stack GST may be configured by including the even conductive layers CDLe, the odd conductive layers CDLo, the first interlayer insulating layers ISL1, and the second interlayer insulating layers ISL2. One even conductive layer CDLe, one second interlayer insulating layer ISL2, and one odd conductive layer CDLo corresponding to one memory group MGR may be defined as one word line stack layer. For example, the first interlayer insulating layers ISL1 and a plurality of word line stack layers may be alternately stacked on a lower structure (not shown). The lower structure may include the substrate or at least one of a source line, a source selection line, and peripheral circuits formed on the substrate.

The even conductive layers CDLe and the odd conductive layers CDLo may be used as a word line or a selection line. For example, assuming that the first interlayer insulating layers ISL1 and the plurality of word line stack layers are alternately stacked on the substrate, at least one even conductive layer CDLe disposed at the lowermost end and at least one odd conductive layer CDLo disposed at the uppermost end may be used as the selection line.

The first interlayer insulating layers ISL1 and the second interlayer insulating layers ISL2 may be formed of oxide, and the even conductive layers CDLe and the odd conductive layers CDLo may include a conductive material such as polysilicon, tungsten, molybdenum, or metal.

In the memory string, a vertical hole VH passing through the first interlayer insulating layers ISL1, the second interlayer insulating layers ISL2, the even conductive layers CDLe, and the odd conductive layers CDLo in the first direction Z which is the vertical direction may be formed. A width of vertical hole VH may be decreased toward a lower end portion. For example, a width of a lower end vertical hole VH_U may be less than a width VH_T of an upper end vertical hole.

The first interlayer insulating layers ISL1 and the second interlayer insulating layers ISL2 may protrude further in a direction adjacent to the vertical hole VH compared to the even conductive layers CDLe and the odd conductive layers CDLo. That is, the blocking insulating layer BOX, the charge trap layer CTN, and the tunnel insulating layer TIL may be interposed in a space between protrusions of the first interlayer insulating layers ISL1 and the second interlayer insulating layers ISL2 adjacent to each other in the first direction Z. That is, the blocking insulating layer BOX, the charge trap layer CTN, and the tunnel insulating layer TIL may be interposed between the even conductive layers CDLe and the odd conductive layers CDLo and the vertical hole VH. In an embodiment of the present disclosure, the blocking insulating layer BOX, the charge trap layer CTN, and the tunnel insulating layer TIL may be defined as a memory structure.

The channel layer CHL may be interposed along a sidewall of the vertical hole VH. For example, the channel layer CHL may be interposed along the sidewall of the vertical hole VH, that is, a sidewall of the first interlayer insulating layers ISL1, the second interlayer insulating layers ISL2, and the tunnel insulating layer TIL. A core insulating layer CO may be interposed in a central region of the vertical hole VH. In an embodiment of the present disclosure, the channel layer CHL and the core insulating layer CO may be defined as a vertical channel structure.

The tunnel insulating layer TIL may be a layer through which a charge is tunneled by F-N tunneling or the like, and may include an insulating material such as oxide or nitride. The charge trap layer CTN may include a plurality of trap sites, and charges flowing through the tunnel insulating layer TIL during the program operation may be trapped. The charge trap layer CTN may include nitride, chalcogenide compound, or metal oxide. The blocking insulating layer BOX may prevent or mitigate the trapped charge in the charge trap layer CTN from moving to the even conductive layers CDLe or the odd conductive layers CDLo, and may include a high dielectric constant material such as aluminum oxide Al₂O₃, hafnium oxide layer HfOx, and hafnium silicon oxide HfSiOx. The channel layer CHL may be used to allow a current to flow in the memory string, and may be formed of polysilicon.

The channel layer CHL may have a cylindrical shape structure extending in the first direction Z which is the vertical direction in the vertical hole VH. The tunnel insulating layer TIL may be formed to surround a portion of an outer sidewall of the channel layer CHL. The charge trap layer CTN may be formed to surround an outer sidewall of the tunnel insulating layer TIL, and the charge trap layer CTN and the tunnel insulating layer TIL corresponding to one memory cell may have a structure separated from the charge trap layer CTN and the tunnel insulating layer TIL corresponding to another memory cell adjacent in the first direction Z which is the vertical direction by the first interlayer insulating layer ISL1 or the second interlayer insulating layer ISL2. Accordingly, in an embodiment, an interference phenomenon and a disturb phenomenon between memory cells adjacent in the first direction Z may be reduced.

In addition, the blocking insulating layer BOX may be formed to surround an outer sidewall of the charge trap layer CTN, and the blocking insulating layer BOX corresponding to one memory cell may have a structure separated from the blocking insulating layer BOX corresponding to another memory cell adjacent in the first direction Z which is the vertical direction by the first interlayer insulating layer ISL1 or the second interlayer insulating layer ISL2.

A vertical thickness of the blocking insulating layer BOX, a vertical thickness of the charge trap layer CTN, and a thickness of the tunnel insulating layer TIL corresponding to one non-volatile memory cell MC may be the same. A sidewall that is in contact with the vertical hole VH of the first interlayer insulating layer ISL1 or the second interlayer insulating layer ISL2 may be positioned on the same line as a sidewall that is in contact with the vertical hole VH of the tunnel insulating layer TIL, or may be formed so that a side portion that is in contact with the vertical hole VH of the first insulating layer ISL1 or the second interlayer insulating layer ISL2 protrudes compared to a sidewall that is in contact with the vertical hole VH of the tunnel insulating layer TIL. In addition, upper surface heights of the even conductive layer CDLe or the odd conductive layer CDLo, the blocking insulating layer BOX, the charge trap layer CTN, and the tunnel insulating layer TIL corresponding to one memory cell may be the same. In addition, lower surface heights of the even conductive layer CDLe or the odd conductive layer CDLo, the blocking insulating layer BOX, the charge trap layer CTN, and the tunnel insulating layer TIL corresponding to one memory cell may be the same.

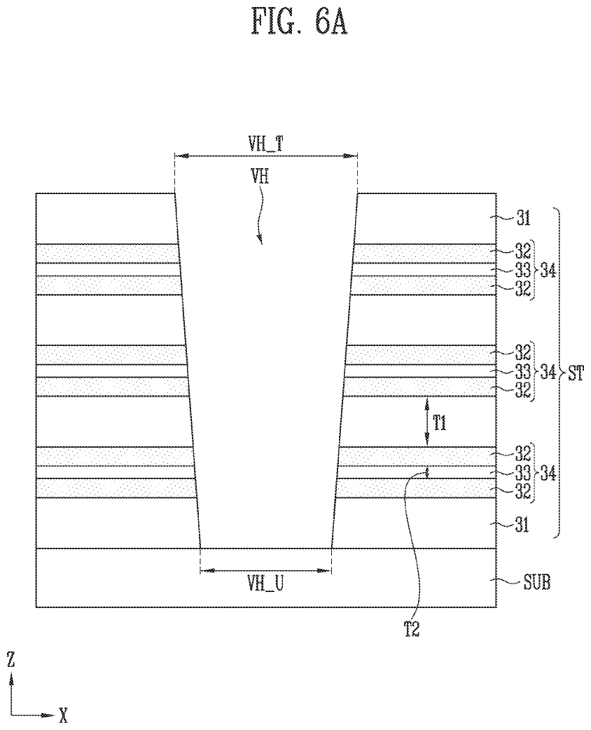

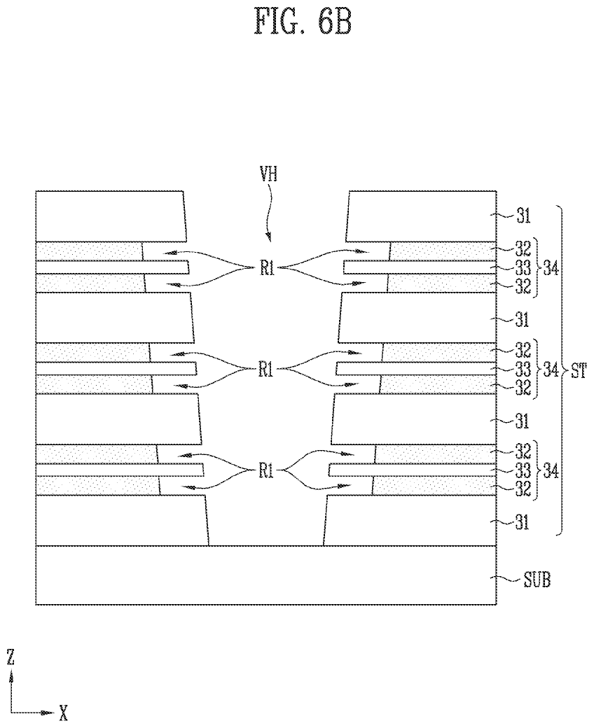

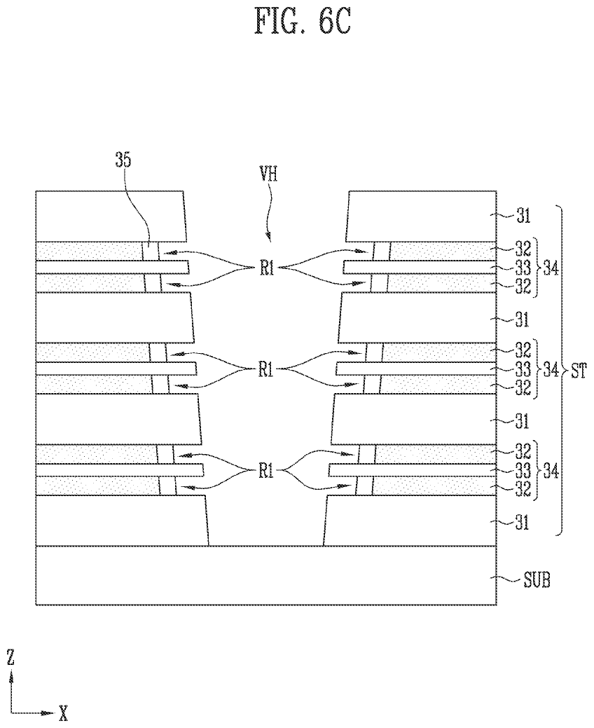

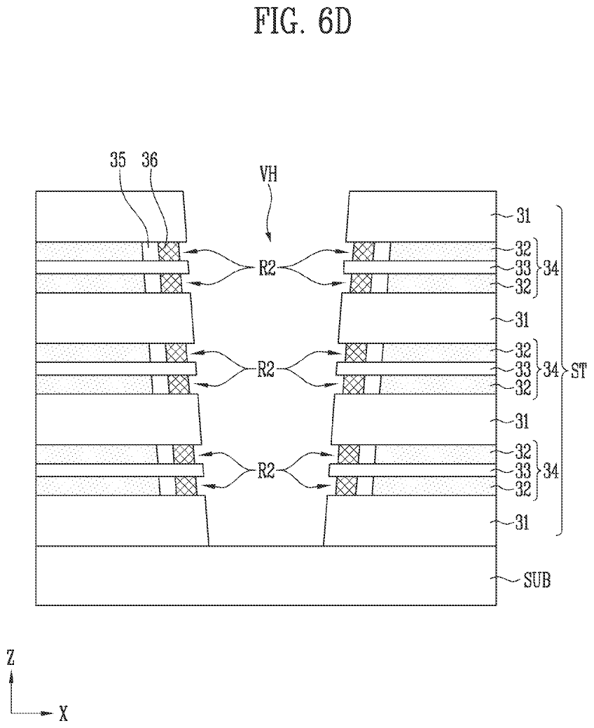

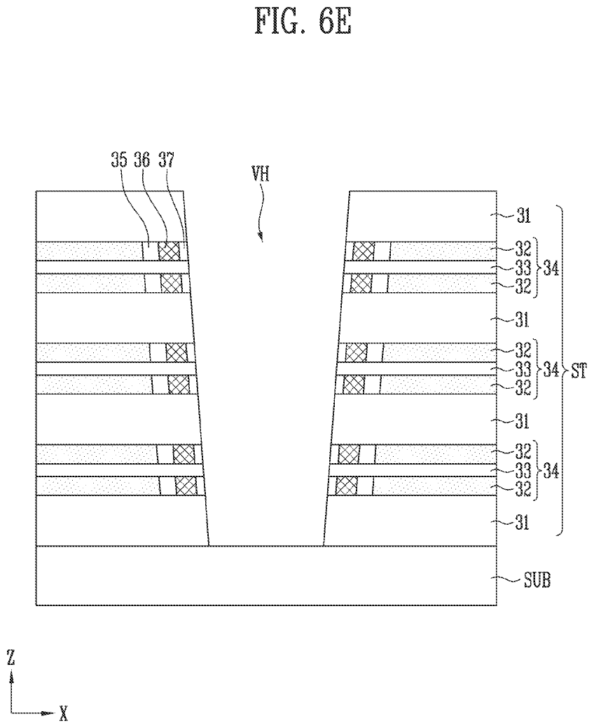

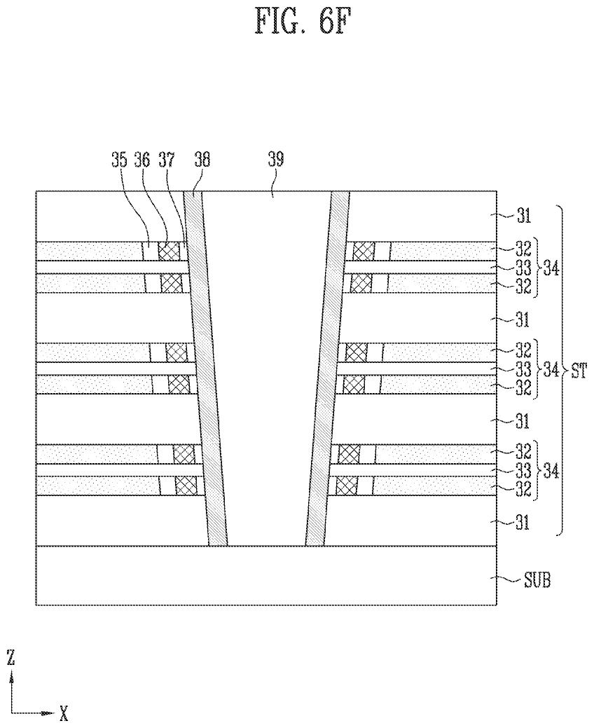

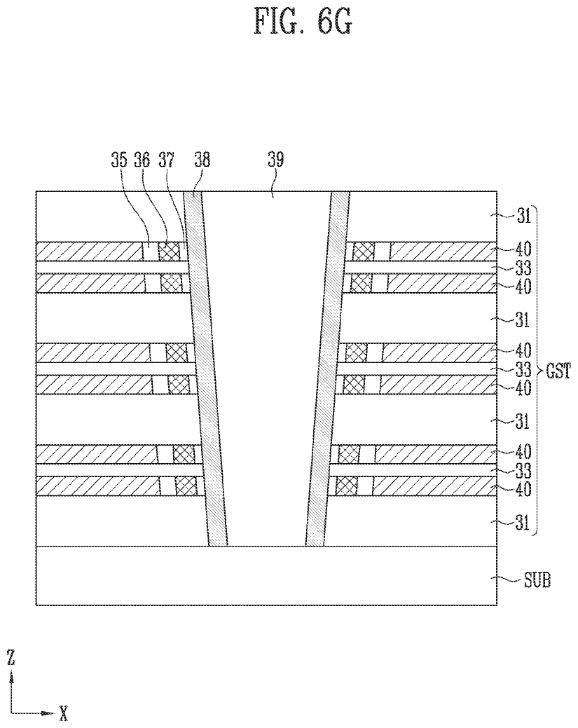

FIGS. 6A to 6G are cross-sectional views illustrating a method of manufacturing a semiconductor device according to an embodiment of the present disclosure.

Referring to FIG. 6A, a stack structure ST is formed on a substrate SUB. The stack structure ST may include first material layers 31 and multi-stack layers 34 alternately stacked. Each of the multi-stack layers 34 may include a second material layer 32, a third material layer 33, and a second material layer 32 sequentially stacked. The first material layers 31, the second material layers 32, and the third material layers 33 may extend in the second direction X which is the horizontal direction of the substrate SUB. The first material layers 31, the second material layers 32, and the third material layers 33 may be stacked in the first direction Z which is the vertical direction of the substrate SUB. The first material layers 31, the second material layers 32, and the third material layers 33 may be formed using a deposition process such as chemical vapor deposition (CVD).

A thickness T1 of the first material layers 31 may be greater than a thickness T2 of the third material layers 33.

The first material layers 31 and the third material layers 33 may include a material having a high etch selectivity with respect to the second material layers 32. As an example, the first material layers 31 and the third material layers 33 may include an insulating material such as oxide, and the second material layers 32 may include a sacrificial material such as nitride. As another example, the first material layers 31 and the third material layers 33 may include an insulating material such as oxide, and the second material layers 32 may include a conductive material such as polysilicon, tungsten, molybdenum, or metal.

Subsequently, the vertical hole VH passing through the stack structure ST may be formed. The vertical hole VH may be a cylindrical shape extending in the first direction Z. The vertical hole VH may be formed so that the width VH_T of an upper portion is greater than the width VH_U of a lower portion.

Referring to FIG. 6B, a sidewall of the second material layers 32 exposed through the vertical hole VH may be etched at a certain depth to form a first recess region R1. That is, the sidewall of the second material layers 32 is etched at a certain depth so that the first material layers 31 and the third material layers 33 protrude compared to the second material layers 32 in the second direction X. Accordingly, a sidewall of the vertical hole VH may be formed in a structure in which uneven portions are sequentially disposed in the first direction Z which is the vertical direction of the substrate SUB.

Referring to FIG. 6C, an oxidation process is performed to oxidize the sidewall of the second material layers 32 exposed through the vertical hole VH to form a blocking insulating layer 35. The oxidation process may be performed as a radical oxidation process or a wet oxidation process. The sidewall of the second material layers 32 may be oxidized at a certain thickness by the oxidation process to form the blocking insulating layer 35.

Referring to FIG. 6D, a charge trap layer 36 that is in contact with the blocking insulating layer 35 is formed. For example, the charge trap layer 36 is formed along the sidewall of the vertical hole VH. The charge trap layer 36 may be formed by controlling a thickness so that the first recess region R1 of FIG. 6C is buried. At this time, the charge trap layer 36 may be formed so that the first recess region R1 is completely buried or only a portion of the first recess region R1 is buried. The charge trap layer 36 may include a charge trap material, nitride, a variable resistance material or a nanostructure, a chalcogenide compound, a metal oxide, or a combination thereof. Thereafter, an etching process is performed so that the charge trap layer 36 remains only in the first recess region R1 of FIG. 6C. That is, the charge trap layer formed on a sidewall of the first material layer 31 and the third material layer 33 is removed by etching to physically and electrically separate the charge trap layers 36 formed in the first recess region R1 of FIG. 6C from each other in the first direction Z. That is, the charge trap layers 36 adjacent in the first direction Z have a structure separated from each other by the first material layer 31 and the third material layer 33.

Thereafter, an additional etching process is performed to etch the charge trap layers 36 exposed through the vertical holes VH to a certain depth (i.e., in the X directions) to form a second recess region R2. That is, a sidewall of the charge trap layers 36 is etched at a certain depth so that the first material layers 31 and the third material layers 33 protrude compared to the charge trap layers 36 in the horizontal direction.

Referring to FIG. 6E, a tunnel insulating layer 37 is formed in the second recess region R2 of FIG. 6F. The tunnel insulating layer 37 may be formed to contact the sidewall of the charge trap layers 36 by performing an oxidation process. The tunnel insulating layer 37 may be a layer through which a charge is tunneled by F-N tunneling or the like, and may include an insulating material such as oxide or nitride.

Referring to FIG. 6F, a channel layer 38 is formed along the sidewall of the vertical hole VH of FIG. 6E. The channel layer 38 may include polysilicon.

The channel layer 38 may be formed along the sidewall of the first material layers 31, the sidewall of the third material layers 33, and a sidewall of the tunnel insulating layer 37. The channel layer 38 may be formed to extend in the first direction Z.

Subsequently, a core insulating layer 39 may be formed to fill a central region of the vertical hole VH of FIG. 6E. The core insulating layer 39 may include oxide. When the central region of the vertical hole VH of FIG. 6E is filled with the channel layer 38, a process of forming the core insulating layer 39 may be skipped.

Referring to FIG. 6G, the second material layers 32 of FIG. 6F are replaced with conductive layers 40. For example, the stack structure ST of FIG. 6F is etched to form a slit extending in the first direction Z to expose a sidewall of the second material layers 32 of FIG. 6F. Subsequently, the second material layers 32 of FIG. 6F exposed through the slit are selectively etched and removed, and a space where the second material layers 32 of FIG. 6F are removed are filled with a conductive material to form the conductive layers 40.

The first material layers 31, the third material layers 33, and the conductive layers 40 may be defined as the gate stack GST.

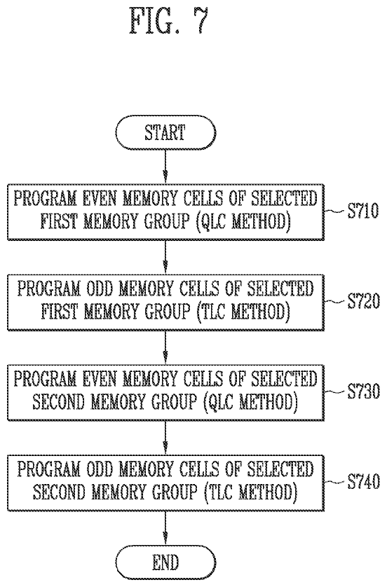

FIG. 7 is a flowchart illustrating a program method of a semiconductor device according to an embodiment of the present disclosure.

The program method of the semiconductor device is described with reference to FIGS. 1, 2, and 7 as follows.

The plurality of even memory cells MCe and the plurality of odd memory cells MCo included in the memory string ST of FIG. 2 may be included in one memory group MGR as described with reference to FIG. 3 or 5, and the thickness T2 of the second interlayer insulating layer ISL2 disposed between the even memory cells MCe and the odd memory cells MCo adjacent to each other in the vertical direction may be less than the thickness T1 of the first interlayer insulating layer ISL1 disposed between the memory groups MGR adjacent to each other.

In step S710, the even memory cells MCe of a first memory group selected from among the plurality of memory groups MGR are programmed. The first memory group may be a memory group MGR adjacent to the source selection transistors SST. The even memory cells MCe of the selected first memory group may be programmed in the QLC method.

The page buffer group 140 applies a program inhibit voltage (for example, a power voltage) or a program allowable voltage (for example, a ground voltage) to the bit lines BL1 to BLm based on the data DATA received during the program operation.

The voltage generator 130 generates a program voltage, a first pass voltage, and a second pass voltage in response to the operation code OPCD. The first pass voltage may have a potential level lower than that of the second pass voltage.

The row decoder 120 applies a program voltage to the even word line WLe corresponding to the first memory group, applies the first pass voltage to the odd word line WLo corresponding to the first memory group, and applies the second pass voltage to the even word lines WLe and the odd word lines WLo corresponding to remaining memory groups according to the row address RADD.

In an embodiment, the first pass voltage of a relatively low level may be applied to the odd memory cells MCo of the first memory group spaced apart by the thickness T2 of the second interlayer insulating layer ISL2 in the vertical direction from the even memory cells MCe of the selected first memory group during the program operation, a disturb phenomenon of the odd memory cells MCo of the first memory group due to the program voltage applied to the even word line WLe may be suppressed.

In step S720, the odd memory cells MCo of the first memory group selected from among the plurality of memory groups MGR are programmed. The odd memory cells MCo of the selected first memory group may be programmed in a program method of which a storage bit is lower than that of the program method of the even memory cells MCe of the first memory group. For example, the odd memory cells MCo of the selected first memory group may be programmed in the TLC method. Because the odd memory cells MCo of the first memory group close to the even memory cells MCe of the first memory group may be vulnerable to interference, disturbance or the like, the odd memory cells MCo may be programmed in a program method with relatively high data stability.

The voltage generator 130 generates the program voltage, the first pass voltage, and the second pass voltage in response to the operation code OPCD. The first pass voltage may have a potential level lower than that of the second pass voltage.

The row decoder 120 applies the program voltage to the odd word line WLo corresponding to the first memory group, applies the first pass voltage to the even word line WLe corresponding to the first memory group, and applies the second pass voltage to the even word lines WLe and the odd word lines WLo corresponding to remaining memory groups according to the row address RADD.

In step S730, the even memory cells MCe of a second memory group selected from among the plurality of memory groups MGR are programmed. The second memory group may be a memory group adjacent to the first memory group. The even memory cells MCe of the selected second memory group may be programmed in the QLC method.

In step S740, the odd memory cells MCo of the second memory group selected from among the plurality of memory groups MGR are programmed. The odd memory cells MCo of the selected second memory group may be programmed in a program method of which a storage bit is lower than that of the program method of the even memory cells MCe of the second memory group. For example, the odd memory cells MCo of the selected second memory group may be programmed in the TLC method.

Thereafter, the program operation may be performed by sequentially selecting to the last selected memory group among the plurality of memory groups MGR.

As described above, according to an embodiment of the present disclosure, data stability may be improved by programming the even memory cells and the odd memory cells included in the selected memory group in different program methods during the program operation of the semiconductor device. In addition, a disturb phenomenon may be improved by applying the first pass voltage lower than the second pass voltage to the odd memory cells relatively close to the even memory cells during the program operation of the even memory cells included in the selected memory group.

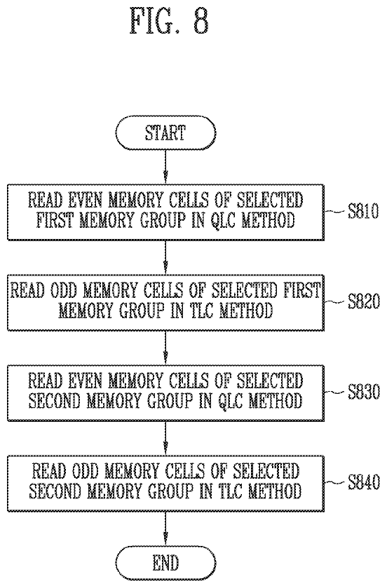

FIG. 8 is a flowchart illustrating a read method of a semiconductor device according to an embodiment of the present disclosure.

The read method of the semiconductor device is described with reference to FIGS. 1, 2, and 8 as follows.

The plurality of even memory cells MCe and the plurality of odd memory cells MCo included in the memory string ST of FIG. 2 may be included in one memory group MGR as described with reference to FIG. 3 or 5, and the thickness T2 of the second interlayer insulating layer ISL2 disposed between the even memory cells MCe and the odd memory cells MCo adjacent to each other in the vertical direction may be less than the thickness T1 of the first interlayer insulating layer ISL1 disposed between the memory groups MGR adjacent to each other.

In step S810, the even memory cells MCe of a first memory group selected from among the plurality of memory groups MGR are read. The first memory group may be a memory group MGR adjacent to the source selection transistors SST. The even memory cells MCe of the selected first memory group may be read in the QLC method when the even memory cells MCe of the selected first memory group are programmed in the program operation.

The voltage generator 130 generates a plurality of read voltages, a first pass voltage, and a second pass voltage in response to the operation code OPCD. The first pass voltage may have a potential level lower than that of the second pass voltage.

The row decoder 120 applies the plurality of read voltages to the even word line WLe corresponding to the first memory group, applies the first pass voltage to the odd word line WLo corresponding to the first memory group, and applies the second pass voltage to the even word lines WLe and the odd word lines WLo corresponding to remaining memory groups according to the row address RADD.

The page buffer group 140 senses data based on a potential level or a current amount of the bit lines BL1 to BLm.

In an embodiment, the first pass voltage of a relatively low level may be applied to the odd memory cells MCo of the first memory group spaced apart by the thickness T2 of the second interlayer insulating layer ISL2 in the vertical direction from the even memory cells MCe of the selected first memory group during the read operation, a disturb phenomenon of the odd memory cells MCo of the first memory group may be suppressed.

In step S820, the odd memory cells MCo of the first memory group selected from among the plurality of memory groups MGR are read. The odd memory cells MCo of the selected first memory group may be read in the TLC method when the odd memory cells MCo of the selected first memory group are programmed in the TLC method in the program operation.

The voltage generator 130 generates the plurality of read voltages, the first pass voltage, and the second pass voltage in response to the operation code OPCD. The first pass voltage may have a potential level lower than that of the second pass voltage.

The row decoder 120 applies the plurality of read voltages to the odd word line WLo corresponding to the first memory group, applies the first pass voltage to the even word line WLe corresponding to the first memory group, and applies the second pass voltage to the even word lines WLe and the odd word lines WLo corresponding to remaining memory groups according to the row address RADD.

The page buffer group 140 senses data based on the potential level or the current amount of the bit lines BL1 to BLm.

In an embodiment, the first pass voltage of a relatively low level may be applied to the even memory cells MCe of the first memory group spaced apart by the thickness T2 of the second interlayer insulating layer ISL2 in the vertical direction from the odd memory cells MCo of the selected first memory group during the read operation, a disturb phenomenon of the even memory cells MCe of the first memory group may be suppressed.

In step S830, the even memory cells MCe of a second memory group selected from among the plurality of memory groups MGR are read. The second memory group may be a memory group adjacent to the first memory group. The even memory cells MCe of the selected second memory group may be read in the QLC method when the even memory cells MCe of the selected second memory group are programmed in the QLC method in the program operation.

In step S840, the odd memory cells MCo of the second memory group selected from among the plurality of memory groups MGR are read. The odd memory cells MCo of the selected second memory group may be read in the TLC method when the odd memory cells MCo of the selected second memory group are programmed in the TLC method in the program operation.

As described above, according to an embodiment of the present disclosure, during the read operation of the even memory cells included in the selected memory group, the first pass voltage lower than the second pass voltage may be applied to the odd memory cells relatively close to the even memory cells, and during the read operation of the odd memory cells included in the selected memory group, the first pass voltage lower than the second pass voltage may be applied to the even memory cells relatively close to the odd memory cells, thereby improving a disturb phenomenon.

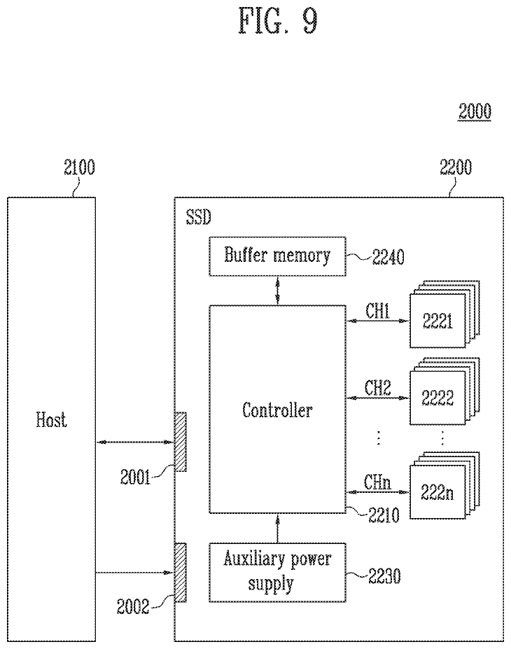

FIG. 9 is a diagram illustrating a solid state drive (SSD) system to which a memory device of the present disclosure is applied.

Referring to FIG. 9, the SSD system 2000 includes a host 2100 and an SSD 2200. The SSD 2200 exchanges a signal with the host 2100 through a signal connector 2001 and receives power through a power connector 2002. The SSD 2200 includes a controller 2210, a plurality of memory devices 2221 to 222n, an auxiliary power supply 2230, and a buffer memory 2240.

The controller 2210 may control the plurality of memory devices 2221 to 222n in response to the signal received from the host 2100. For example, the signal may be signals based on an interface between the host 2100 and the SSD 2200. For example, the signal may be a signal defined by at least one of interfaces such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe.

The plurality of memory devices 2221 to 222n may be configured to store data and include a plurality of non-volatile memory cells. Each of the plurality of memory devices 2221 to 222n may be configured identically to the semiconductor device 1100 shown in FIG. 1.

The auxiliary power supply 2230 is connected to the host 2100 through the power connector 2002. The auxiliary power supply 2230 may receive a power voltage from the host 2100 and charge the power voltage. The auxiliary power supply 2230 may provide a power voltage of the SSD 2200 when power supply from the host 2100 is not smooth. For example, the auxiliary power supply 2230 may be positioned in the SSD 2200 or may be positioned outside the SSD 2200. For example, the auxiliary power supply 2230 may be positioned on a main board and may provide auxiliary power to the SSD 2200.

The buffer memory 2240 operates as a buffer memory of the SSD 2200. For example, the buffer memory 2240 may temporarily store data received from the host 2100 or data received from the plurality of memory devices 2221 to 222n, or may store meta data (for example, a mapping table) of the plurality of memory devices 2221 to 222n. The buffer memory 2240 may include volatile memory such as DRAM (dynamic random access memory), SDRAM (synchronous DRAM), DDR SDRAM (double data rate SDRAM), and LPDDR SDRAM (low-power DDR SDRAM), or non-volatile memory such as FRAM (ferroelectric random access memory), ReRAM (resistive random access memory), STT-MRAM (Spin-transfer Torque Magnetic random access memory), and PRAM (Parameter Random Access Memory).

What is claimed is:

1. A semiconductor device comprising:
a gate stack including first interlayer insulating layers and word line stack layers, which are alternately stacked;
a channel layer extending in a vertical direction in the gate stack; and
memory structures interposed between the word line stack layers and the channel layer,
wherein each of the word line stack layers includes an even conductive layer, a second interlayer insulating layer, and an odd conductive layer sequentially stacked, and
the thickness of each of the first interlayer insulating layers is greater than the thickness of any one of the second interlayer insulating layers included in any one of the word line stack layers.

2. The semiconductor device of claim 1, wherein each of the memory structures includes a blocking insulating layer and a charge trap layer sequentially interposed between sidewalls of the even conductive layer and the odd conductive layer, and
a sidewall of the first interlayer insulating layers and the second interlayer insulating layer contacting the channel layer is positioned on the same line as a sidewall of the charge trap layer contacting the channel layer, or a side portion of the first interlayer insulating layers and the second interlayer insulating layer contacting the channel layer protrudes further towards the sidewall of the channel layer than the charge trap layer protrudes towards the sidewall of the channel layer.

3. The semiconductor device of claim 1, wherein the first interlayer insulating layers and the second interlayer insulating layer further protrude in a direction of the channel layer than does the even conductive layer and the odd conductive layer, and
the blocking insulating layer and the charge trap layer are interposed in a space between the protruded first interlayer insulating layers and the second interlayer insulating layer.

4. The semiconductor device of claim 1, wherein the charge trap layer interposed between the sidewalls of each of the even conductive layer and the odd conductive layer is spaced apart from each other by the first interlayer insulating layers and the second interlayer insulating layer.

5. The semiconductor device of claim 2, further comprising a tunnel insulating layer extending in the vertical direction along a sidewall of the first interlayer insulating layers, a sidewall of the second interlayer insulating layer, and a sidewall of the charge trap layer,
wherein the channel layer extends in the vertical direction along a sidewall of the tunnel insulating layer.

6. A semiconductor device comprising:
a gate stack including first interlayer insulating layers and word line stack layers, which are alternately stacked;
a channel layer extending in a vertical direction in the gate stack; and
memory structures interposed between the word line stack layers and the channel layer,
wherein each of the word line stack layers includes an even conductive layer, a second interlayer insulating layer, and an odd conductive layer sequentially stacked,
wherein each of the memory structures includes a blocking insulating layer, a charge trap layer, and a tunnel insulating layer sequentially interposed between sidewalls of the even conductive layer and the odd conductive layer, and
wherein the thickness of any one of the first interlayer insulating layers is greater than the thickness of any one of the second interlayer insulating layers.

7. The semiconductor device of claim 6, wherein the thickness of any one of the first material layers is greater than the thickness of any one of the third material layer.

8. The semiconductor device of claim 6, wherein the first interlayer insulating layers and the second interlayer insulating layer further protrude in a direction toward the channel layer than compared to the even conductive layer and the odd conductive layer, and
the blocking insulating layer, the charge trap layer, and the tunnel insulating layer are interposed in a space between the protruded first interlayer insulating layers and the second interlayer insulating layer.

9. The semiconductor device of claim 6, wherein the charge trap layer interposed between the sidewalls of each of the even conductive layer and the odd conductive layer is spaced apart from each other by the first interlayer insulating layers and the second interlayer insulating layer.
